(19) United States
(12) Patent Application Publication
(10) Pub. No.: US 2020/0194071 A1
(43) Pub. Date: Jun. 18, 2020

(54) NONVOLATILE MEMORY WITH A TEMPERATURE RECORDING FUNCTION AND OPERATION METHOD THEREOF

(71) Applicants: GigaDevice Semiconductor (Beijing) Inc., Beijing (CN); GigaDevice Semiconductor (Shanghai) Inc., Shanghai (CN)

(72) Inventor: Minyi Chen, Beijing (CN)

(73) Assignees: GigaDevice Semiconductor (Beijing) Inc., Beijing (CN); GigaDevice Semiconductor (Shanghai) Inc., Shanghai (CN)

(21) Appl. No.: 16/236,609

(22) Filed: Dec. 30, 2018

(30) Foreign Application Priority Data
Dec. 13, 2018 (CN) 201811523914.0

(51) Int. Cl. G11C 16/10; G11C 16/04; G11C 16/14; G11C 16/34

(52) U.S. Cl. CPC G11C 16/10; G11C 16/0483; G11C 16/3459; G11C 16/3445; G11C 16/14

(57) ABSTRACT

A nonvolatile memory includes: a memory cell array having a first portion and a second portion, a temperature sensor configured to measure a temperature of the memory cell array, and a controller. The first portion is programmable, readable and erasable to a predefined user, and the second portion is not programmable and erasable to the predefined user. The controller is configured to: perform an operation in the first portion in response to an instruction of the purchaser, and in response to determining that a predetermined condition is satisfied, write the temperature of the memory cell array when doing the operation and operation information related to the operation into the second portion.

### CROSS-REFERENCE TO RELATED APPLICATIONS

This application claims priority to a Chinese patent application No. 201811523914.0 filed on Dec. 13, 2018, the disclosure of which is incorporated herein by reference in its entirety.

### TECHNICAL FIELD

Embodiments of the present disclosure relate generally to semiconductor memory devices. More particularly, embodiments of the present disclosure relate to a nonvolatile memory, and an operation method of the nonvolatile memory.

### BACKGROUND

Nonvolatile memory device is widely used for data storage applications, and becomes an indispensable component of modern electronic systems, such as personal computers, cellular phones, digital cameras, automotive systems, global positioning systems and the like. Data stored in the nonvolatile memory is not lost when the power supply is removed.

Examples of nonvolatile memory devices include read only memory (ROM), programmable ROM (PROM), electrically programmable ROM (EPROM), electrically erasable PROM (EEPROM), flash memory, phase-change random access memory (PRAM), magnetic random access memory (MRAM), resistive random access memory (RRAM), and ferroelectric random access memory (FRAM).

Among nonvolatile memory devices, flash memory has achieved increasing popularity in recent years due to a variety of attractive features, such as relatively high storage capacity and performance, and relatively low power consumption and cost. In flash memory, floating-gate transistor is typically used as the flash memory cell. The floating-gate transistor changes with age and such change may ultimately lead to memory cell failure. The memory cell failure may be caused by other factors, for example, working environment and improper operation performed on the flash memory. Failure analysis is very important to the development of the next generation flash memory.

### SUMMARY

The following is a summary of a subject matter described herein in detail.

According to a first aspect of the present disclosure, a nonvolatile memory includes: a memory cell array having a first portion and a second portion, a temperature sensor configured to measure a temperature of the memory cell array, and a controller. The first portion is programmable, readable and erasable to a predefined user, and the second portion is not programmable and erasable to the predefined user. The controller is configured to: perform an operation in the first portion in response to an instruction of the predefined user, and in response to determining that a predetermined condition is satisfied, write the temperature information of the memory cell array when doing the operation and operation information related to the operation into the second portion.

According to a second aspect of the present disclosure, a program method for a nonvolatile memory is provided. The nonvolatile memory includes: a memory cell array having a first portion and a second portion and a temperature sensor configured to measure a temperature of the memory cell array. The first portion is programmable, readable and erasable to a user, and the second portion is not programmable and erasable to the user. The program method includes performing a program operation in the first portion in response to a program instruction of the user, and in response to determining that a predetermined condition is satisfied, writing the temperature information of the memory cell array when doing the program operation and operation information related to the program operation into the second portion.

The operation information includes at least one of: an operation type, a magnitude of a program voltage, a sequence number of the program operation, a first status indicating whether the program operation succeeds or fails, a second status indicating whether the temperature of the memory cell array is within a predetermined range, and an address of memory cells in the first portion where the program operation is performed.

According to a third aspect of the present disclosure, an erase method for a nonvolatile memory is provided. The nonvolatile memory includes: a memory cell array having a first portion and a second portion and a temperature sensor configured to measure a temperature of the memory cell array. The first portion is programmable, readable and erasable to a user, and the second portion is not programmable and erasable to the user. The erase method includes: performing an erase operation in the first portion in response to an erase instruction of the user, and in response to determining that a predetermined condition is satisfied, writing the temperature information of the memory cell array when doing the erase operation and operation information related to the erase operation into the second portion.

The operation information includes at least one of: an operation type, a magnitude of an erase voltage, a sequence number of the erase operation, a first status indicating whether the erase operation succeeds or fails, a second status indicating whether the temperature of the memory cell array is within a predetermined range, and an address of memory cells in the first portion where the erase operation is performed

In an exemplary embodiment, the predetermined condition is that the temperature of the memory cell array is out of a predetermined range.

In an exemplary embodiment, the predetermined condition is that the operation performed in the first portion fails.

In an exemplary embodiment, the predetermined condition is that the operation is performed in the first portion. That is, no matter the operation performed in the first portion succeeds or fails, the temperature information and the operation information related to this operation are wrote into the second portion.

In an exemplary embodiment, the temperature information and the operation information are used for failure analysis.

### BRIEF DESCRIPTION OF DRAWINGS

The accompanying drawings are used for providing further understanding of the present disclosure and constitute a part of this specification. Elements and/or components in the figures are not necessarily drawn to scale.

FIG. 1 is a simplified block diagram of a flash memory according to an embodiment of the present disclosure.

FIG. 2 is a schematic diagram of a flash memory cell array according to an embodiment of the present disclosure.

FIG. 3 is a schematic diagram of an exemplary configuration of a flash memory block according to an embodiment of the present disclosure.

FIG. 4 is a simplified block diagram of an exemplary configuration of a controller and a flash memory cell array according to an embodiment of the present disclosure.

FIG. 5 is a simplified block diagram of another exemplary configuration of a controller and a flash memory cell array according to an embodiment of the present disclosure.

FIG. 6 is a simplified block diagram of a read circuit according to an embodiment of the present disclosure.

FIG. 7 is a schematic diagram of a program voltage in an NW method according to an embodiment of the present disclosure.

FIG. 8 is a flowchart of an exemplary operation method of the flash memory according to an embodiment of the present disclosure.

FIG. 9 is a flowchart of another exemplary operation method of the flash memory according to an embodiment of the present disclosure.

FIG. 10 is a flowchart of yet another exemplary operation method of the flash memory according to an embodiment of the present disclosure.

### DETAILED DESCRIPTION

The present disclosure is described more fully hereinafter with reference to the accompanying drawings, in which embodiments of the invention are shown. This invention may be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes or configurations of elements may be idealized or exaggerated for clarity.

It will be understood that when an element is referred to as being “connected to” another element, it may be directly connected to the other element or intervening elements may be present. In contrast, when an element is referred to as being “directly connected to” another element, there are no intervening elements present. Like numbers refer to like elements throughout. As used herein, the term “and/or” includes any and all combinations of one or more of the associated listed items.

It will be understood that, although the terms first, second, third etc. may be used herein to describe various elements, components and/or sections, these elements, components and/or sections should not be limited by these terms. These terms are only used to distinguish one element, component, or section from another element, region or section. Thus, a first element, component or section discussed below could be termed a second element, component or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” and/or “include” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

In the past decade, advances in flash memories including NAND flash memory and NOR flash memory have increased the flash capacity and flash density by thousands of times. This rapid increase in flash capacity and flash density have brought a decrease in flash memory reliability. For example, the number of times that a memory cell can be reliably programmed and erased before wearing out drops remarkably with the sealing down of the size of the memory cell and the using of the 3D structure. It is very important for us to fully understand the failing root of the flash memory.

Temperature is a very important parameter for the failure analysis of the flash memory. Operating temperature of flash memories in conventional consumer products ranges from −40° C. to 85° C. Operating temperature of flash memories in automotive products generally ranges from −40° C. to 105° C. Operating temperature of flash memories in military products generally ranges from −40° C. to 125° C. A traceable mechanism is expected to understand the failure root of the flash memory.

FIG. 1 is a simplified block diagram of an exemplary flash memory 10 suitable for implementing aspects of the present disclosure. The flash memory 10 shown in FIG. 1 has been simplified to focus on particular elements to improve understanding the present disclosure. As shown in FIG. 1, the flash memory 10 includes a flash memory cell array 100, a controller 200, and a temperature sensor 300. The temperature sensor 300 is configured to measure the temperature of the flash memory cell array 100. In an exemplary embodiment, the temperature sensor 300 is triggered when a read operation is performed, or when a program operation is performed or when an erase operation is performed. The flash memory cell array 100 includes a first portion 110 and a second portion 120. In an exemplary embodiment, the capacity of the first portion 110 has a greater capacity than the second portion 120.

In an exemplary embodiment, the first portion 110 is available to a first user and a second user, while the second portion 120 is only available to the first user and not available to the second user. For example, the first user is the technical staff of the manufacturer of the flash memory 10 or the developer of the flash memory 10, and the second user is the purchaser (end user) of the flash memory 10. The first portion 110 is programmable, readable, and erasable to the first user and the second user. In other words, the first portion 110 is released to the purchaser, while the second portion 120 is not released to the purchaser. The purchaser stores data in the first portion 110 in daily work.

The second portion 120 may be protected using software protection or hardware protection. A command or password is required to disable the software protection or hardware protection, and the purchaser of the flash memory 10 is not aware of such command or password. Therefore, the second portion 120 is prevented from being modified (program, read and erase) by the purchaser of the flash memory 10.

In various embodiments, the second portion 120 is a region protected by a system command. When the flash memory 10 leaves the factory, the second portion 120 is blank, and no data is stored therein. Data may be wrote (programmed) into the second portion 120 only when a predetermined condition is satisfied. Once a memory cell (for example, a field-effect transistor having a charge trapping layer) in the second portion 120 is programmed (that is, data is wrote into this memory cell), this memory cell is permanently prevented from being modified (programmed or erased), so the second portion 120 is referred to as a one-time program (OTP) region.

In an alternative embodiment, the second portion 120 may be readable to the purchaser, but not programmable and erasable to the purchaser. The purchaser may see the data stored in the second portion 120, but cannot modify the data.

The controller 200 is configured to perform the program operation, the erase operation and the read operation on the first portion 110 of the flash memory cell array 100 in response to an instruction of the first user and/or the second user. The controller 200 is further configured to perform the program operation on the second portion 120 when the predetermined condition is satisfied, and prevent the memory cells in the second portion 120 which have been programmed from being programmed again and erased.

Hereinafter, an NAND flash memory is used for describing the flash memory 10 of the present disclosure. It should be noted that the flash memory 10 of the present disclosure may be an NOR flash memory, an EPROM, an EEPROM, an PRAM, an MRAM, an RRAM, an FRAM, a 3D NAND flash memory and the like.

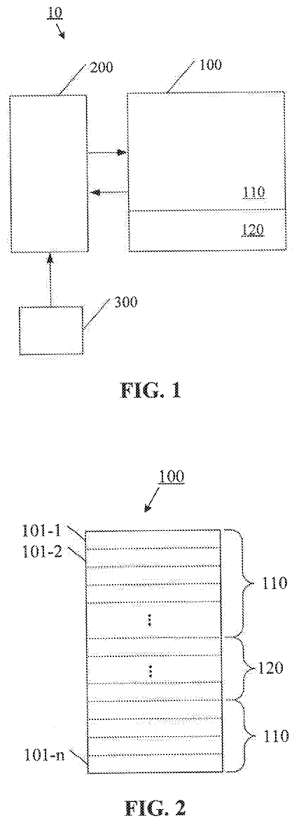

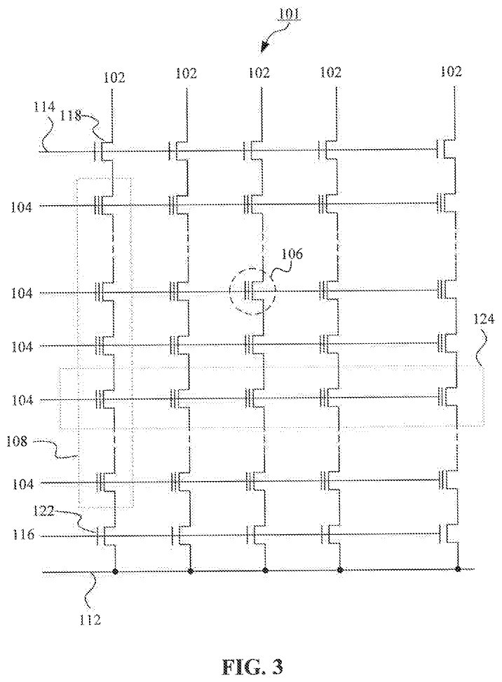

In this exemplary embodiment, the flash memory 10 is a NAND flash memory, and the flash memory cell array 100 may be a two-dimensional flash memory cell array, or a three-dimensional stack of flash memory cells, such as 3D NAND flash memory. FIG. 2 is a schematic diagram of the flash memory cell array 100. As shown in FIG. 2, the flash memory cell array 100 includes multiple blocks 101-1 to 101-n. The first portion 110 includes the majority of the multiple blocks. The second portion 120 includes at least one block which do not belong to the first portion 110. For example, the second portion 120 includes blocks 101-i to 101-j, and the first portion includes blocks 101-1 to 101-(i−1) and blocks 101-(j+1) to 101-n.

In an exemplary embodiment, the flash memory cell array 100 may further include a third portion which is permanently prevented from being modified by the purchaser. Parameter tables and information related to operation management of the flash memory 10 are programmed into the third portion before the flash memory 10 leaves the factory.

FIG. 3 is a schematic diagram illustrating an exemplary configuration of the block 101. As shown in FIG. 3, the flash memory cells 106 are arranged in rows and columns. The flash memory cells 106 in the column direction are connected in series to constitute a string 108. Specifically, the flash memory cells 106 in a same string are daisy-chained by their sources and drains. Each string 108 is connected to a bit line 102 via a first select switch 118. Data can be read via the bit line 102 by a sense amplifier which will be described below. The first select switch 118 controls the connection and disconnection between the string 108 and the hit line 102. The first select switch 118 is controlled by a first control signal line 114. Each string 108 is further connected to a common source line 112 via a second select switch 122. The second select switch 122 is controlled by a second control signal line 116. The flash memory cells 106 in the row direction share a same word line 104, and constitute one page 124. In other words, control gates of the flash memory cells 106 in a same page are all connected to a same word line 104. Each block 101 includes multiple pages 124.

The flash memory cell 106 may be implemented by, a field-effect transistor having a charge trapping layer sandwiched between two oxide layers. The charge trapping layer may be a floating gate or a charge trapping dielectric layer.

Operations on the flash memory typically include program, erase and read. For the NAND flash memory, the erase operation is performed in block, while the program operation and the read operation are performed in page. The flash memory cell 106 has a programmed state and an erased state. When the flash memory cell 106 is in the programmed state, the flash memory cell 106 is regarded as storing information “0”, When the flash memory cell 106 is in the erased state, the flash memory cell 106 is regarded as storing information “1”.

The program, erase and read operations are described with an exemplary embodiment in which the flash memory cell 106 is fabricated in a p-well.

In the program operation, a program voltage is applied to the word line 104 that is connected to the control gate of a selected flash memory cell 106, a voltage Vₚₐₛₛ is applied to control gates of unselected flash memory cells 106 in the same string 108, and a voltage of 0V is applied to the bit line 102 of the selected flash memory cell 106, such that electrons in the p-well move into the floating gate by tunneling and are trapped in the floating gate.

In the erase operation, a small voltage (for example, 0-0.5V) is applied to the control gate of the flash memory cell 106 via the word line 104, and an erase voltage. (fix example, 20V) is applied to the p-well, such that the electrons trapped in the floating gate move to the p-well.

In the read operation, a read voltage is applied to the control gate of the selected flash memory cell 106 and another voltage is applied to the source of the flash memory cell 106, the voltage Vₚₐₛₛ is applied to control gates of unselected flash memory cells 106 in the same string 108. The current on the bit line 102 is measured and compared with a reference current to determine whether the selected flash memory cell 106 stores information “0” or information “1”.

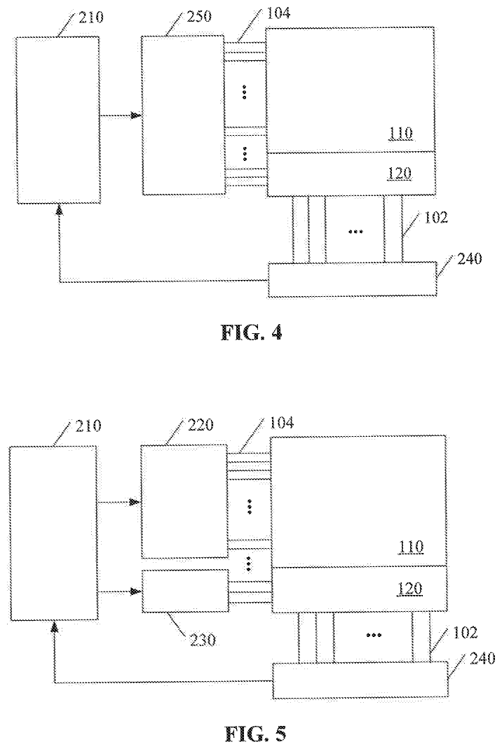

In an exemplary embodiment, as shown in FIG. 4, the controller 200 includes a processor 210, an address circuit 250, and a read circuit 240. The address circuit 250 is electrically connected to all of the word lines 104 of the flash memory cell array 100. The address circuit 250 can address all the flash memory cells 106 in the flash memory cell array 100. Specifically, the address circuit 250 receives an address signal from the processor 210, and addresses the target block to be erased or the target page to be read or programmed by decoding the address signal. The read circuit 240 is connected to the hit lines 102.

In an alternative embodiment, as shown in FIG. 5, the controller 200 includes a processor 210, a first address circuit 220, a second address circuit 230 and a read circuit 240. The first address circuit 220 is configured to address the flash memory cells 106 in the first portion 110. The first address circuit 220 is unable to address the flash memory cells 106 in the second portion 120. The second address circuit 230 is configured to address the flash memory cells 106 in the second portion 120, and is unable to address the flash memory cells 106 in the first portion 110. In this embodiment, the control of the first portion 110 and the control of the second portion 120 are separated, such that the second portion 120 is protected better.

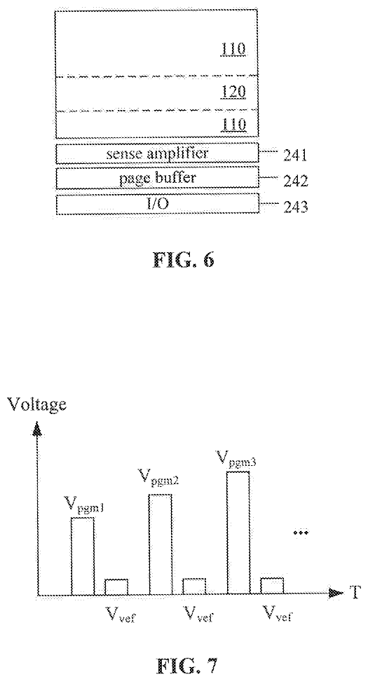

FIG. 6 is a schematic diagram of the read circuit 240. As shown in FIG. 6, the read circuit 240 includes a sense amplifier 241, a page buffer 242 and an I/O circuit 243. The sense amplifier 241 is connected to the bit lines 102 of the flash memory cell array 100. The information stored in the flash memory cells 106 of the selected page can be read simultaneously by the sense amplifier 241, and then stored in the page buffer 242, and outputted to the processor 210 via the I/O circuit 240.

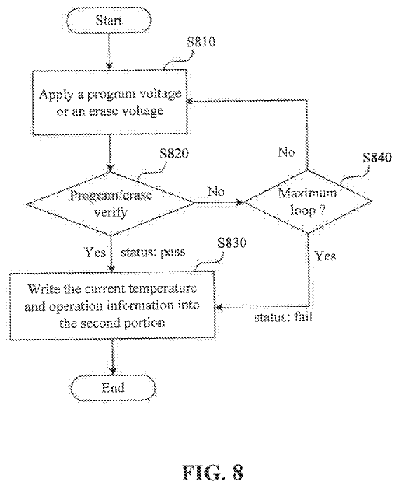

Typically, an Incremental Step Pulse Program (NIP) method is employed in the program operation, that is, one or more incremental voltage pulses are applied to the word line 104 of the selected page. FIG. 7 is a schematic diagram illustrating the voltage waveform in the ISPP method. In the first program loop, an initial program voltage V_{pgm1} is applied to the word line 104, and then the program voltage T_{pgm1} is removed, and then a verify voltage Vᵥₑᵣ is applied to the word line 104 to find out how many flash memory cells 106 in the selected page are successfully programmed. The verify voltage Vᵥₑᵣ may be a little larger than the read voltage. If the quantity of the successfully programmed flash memory cells 106 in the selected page is greater than a preset number, it is determined that the selected page is successfully programmed, the program operation succeeds and ends. If the quantity of the successfully programmed flash memory cells 106 in the selected page is less than the preset number, a second program loop is performed. In the second program loop, a second program voltage V_{pgm2} is applied to the word line 104. The second program voltage V_{pgm2} is equal to the sum of the initial program voltage V_{pgm1} and an incremental amount ΔV_{pgm}. In the second program loop, a program inhibit voltage is applied to bit lines 102 electrically connected to the flash memory cells 106 which have been successfully programmed in the first program loop. The verify voltage Vᵥₑᵣ is applied to the word line 104 after the second program voltage V_{pgm2} is removed to find out how many flash memory cells 106 in the selected page are successfully programmed. If the quantity of the successfully programmed flash memory cells 106 in the selected page is still less than the preset number, a third program loop is needed.

If the selected page is not successfully programmed after a preset number of loops, this program operation fails.

Similarly, an Incremental Step Pulse Erase (ISPE) method may be employed in the erase operation.

The controller 200 is configured to perform read, program, and erase operations on the first portion 110 of the flash memory cell array 100 in response to the instruction of the user (such as the purchaser).

When the predetermined condition is satisfied, the controller 200 is configured to write the temperature information of the flash memory cell array 100 when doing the operation and operation information related to the operation performed on the first portion 110 into the second portion 120. In an exemplary embodiment, the operation information may include at least one of: an operation type, address information, a sequence number, information regarding whether this operation succeeds or fails, information regarding whether temperature is within a predetermined range, a magnitude of the operation voltage. The operation type is used for indicating whether the present operation is a program operation or an erase operation or a read operation. The address information is used for indicating the address of the selected flash memory cell 106, such as an address of a block where the erase operation is performed or an address of a page where the program operation or the read operation is performed. The sequence number of the erase operation represents that how many erase operations have been performed on this block up to now, that is the number of the erase operations have been performed on this block from the flash memory 10 leaves the factory to the time when this erase operation is performed. The sequence number of the program operation represents that how many program operations have been performed on this page up to now.

When the ISPP method is used in the program operation, the magnitude of the operation voltage is the magnitude of the initial program voltage, and the operation information further includes the quantity of program loops used in this program operation, and the quantity of flash memory cells 106 in the selected page which are not successfully programmed when this program operation is finished. When the ISPE method is used in the erase operation, the magnitude of the operation voltage is the magnitude of the initial erase voltage, and the operation information further includes the quantity of erase loops used in this erase operation, and the quantity of flash memory cells 106 in the selected block which are not successfully erased when this erase operation is finished.

An exemplary format of the information programmed into the second portion 120 is illustrated below.

| | Column/row | | | Program | Program |
|---|---|---|---|---|---|
| T | address | Status 1 | Status 2 | loops | voltage |
| 60 | m/n | 1 | 0 | 5 | 17 V |

The temperature information may occupy 1 byte and cover a temperature range from −40° C. to 150° C. According to the above information programmed into the second portion 120, the temperature of the flash memory cell array 100 is 60° C., the flash memory cell 106 at the intersection of the mth column and the nth row is programmed. The status 1 may occupy 1 bit and indicates whether this operation succeeds. For example, if the value of the status 1 is “1”, it indicates that the program operation succeeds, if the value of the status 1 is “0”, it indicates that the program operation fails. The status 2 may also occupy 1 bit and indicates whether the temperature of the memory cell array is within a predetermined range. The flash memory is designed to work normally in the predetermined range. For example, the predetermined range is −40° C. to 85° C. In the above table, the value of the status 2 is “0”, it indicates that the temperature of the memory cell array is within a predetermined range. If the value of the status 2 is “1”, the temperature of the memory cell array is out of range. The status “Program loops” indicates that 5 program loops are used in this program operation, and the status “Program voltage” indicates that the initial voltage used in the program operation is 17V. In another embodiment, the status 2 may occupy 2 hits, and accordingly the status 2 has four values. The value “00” indicates that the temperature of the memory cell array is below −40° C. The value “01” indicates that the temperature of the memory cell array is within a range of −40V to 85° C. The value “10” indicates that the temperature of the memory cell array is within a range of 85° C. to 105° C. The value “11” indicates that the temperature of the memory cell array is over 105° C.

In an exemplary embodiment, the predetermined condition for the controller 200 to write data into the second portion 120 is that a program operation or an erase operation is performed in the first portion 110. That is, no matter whether the program operation or the erase operation fails or succeeds, the temperature information and the operation information are wrote into the second portion 120. In order to obtain more data, the temperature information and the operation information are recorded in the second portion 120 after every program operation and every erase operation ever performed on the first portion 110. After the program operation or erase operation in the first portion, the controller 200 records the current temperature of the flash memory cell array 100 and operation information regarding the program operation or erase operation in the first portion 110 into the second portion 120 of the flash memory cell array 100.

FIG. 8 is a flowchart of an exemplary operation method of the flash memory according to an embodiment of the present disclosure. First, in step S810, a program voltage is applied to the word line of the selected page, or an erase voltage is applied to the p-well. Next, in step S820, a program verify or an erase verify is performed to check whether the present program loop or the erase loop succeeds.

In the program or erase verify, the read operation is performed on the flash memory cells 106 of the selected page or the selected block. The processor 210 determines the quantity of the flash memory cells 106 which are not successfully programmed or the quantity of the flash memory cells 106 which are not successfully erased. The quantity of the flash memory cells 106 which are not successfully programmed or the quantity of the flash memory cells 106 which are not successfully erased is compared with a preset number.

If the quantity of the flash memory cells 106 which are not successfully programmed is less than or equal to the preset number, it is determined that the program verify is passed and the program operation is successful. If the quantity of the flash memory cells 106 which are not successfully erased is less than or equal to the preset number, it is determined that the erase verify is passed and the erase operation is successful. The method proceeds to step S830 in which the current temperature of the flash memory and operation information are wrote into the second portion 120 of the flash memory cell array 100.

If the quantity of the flash memory cells 106 which are not successfully programmed is greater than the preset number, it is determined that the program verify is not passed and the program loop is not successful yet. If the quantity of the flash memory cells 106 which are not successfully erased is greater than the preset number, it is determined that the erase verify is not passed and the erase operation is not successful yet. The method proceeds to step S840. In step 840, the program loop number or the erase loop number is compared with a preset value. The preset value represents a maximum number of operation loops allowed to be performed. If the present operation loop is not the maximum loop, the program voltage is increased by ΔV_{pgm}, or the erase voltage is increased by Δₑᵣₐₛₑ. The method goes back to the step S810, the increased program voltage or the increased erase voltage is applied. If the present operation loop is the maximum loop, it is determined that the present program or erase operation fails, and the method proceeds to step S830. The current temperature of the flash memory and operation information are recorded in the second portion 120 of the flash memory cell array 100.

With the above operation method, the temperature information and operation information in each program operation or erase operation are recorded in a portion of the flash memory cell array 100 that is prevented from being modified. If this flash memory cannot work and is returned to the manufacturer, the technical staff may find out the failure root based on these temperature values and operation information.

In another exemplary embodiment, the predetermined condition for the controller 200 to write data into the second portion 120 is that a program operation or an erase operation is performed in the first portion 110 and the temperature of the flash memory cell array 100 is out of a predetermined temperature range.

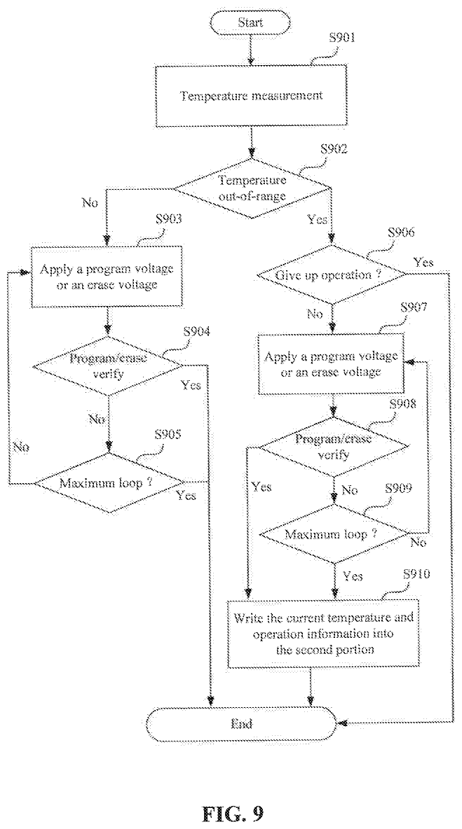

FIG. 9 is a flowchart of another exemplary operation method of the flash memory according to an embodiment of the present disclosure. When the processor 210 receives a program instruction or an erase instruction in the first portion, the operation method starts. As shown in FIG. 9, in step S901, the current temperature of the flash memory cell array 100 is measured. Next, in step S902, it is determined whether the temperature is out of a predetermined temperature range. For the flash memory in a consumer product, the preset temperature range may be −40° C. to 85° C.

If it is determined that the current temperature of the flash memory cell array 100 is within the predetermined temperature range, the method proceeds to step S903. In step S903, a program voltage is applied to the word line of the selected page, or an erase voltage is applied to the p-well. Next, in step S904, a program verify or an erase verify is performed. If the program verify or the erase verify is passed, the method ends. If the program verify or the erase verify is not passed, the method proceeds to step S905 in which it is determined whether the present operation loop is the maximum loop or not. If the present operation loop is the maximum loop, it is determined that the present operation fails and the method ends. If the present operation loop is not the maximum loop, the method goes hack to step S903, and an increased program voltage or an increased erase voltage is applied.

If it is determined that the current temperature of the flash memory cell array 100 is out of the predetermined temperature range, the method proceeds to step S906 in which it is determined whether to give up this operation. If it is determined to give up this operation, the method ends. If it is determined to proceed this operation, the method proceeds to step S907. In step S907, a program voltage is applied to the word line of the selected page, or an erase voltage is applied to the p-well. Next, in step S908, a program verify or an erase verify is performed. If the program verify or the erase verify is passed, it is indicated that the program operation or the erase operation succeeds and the method proceeds to step S910. In step S910, the current temperature information and operation information are wrote into the second portion.

If the program verify or the erase verify in step S908 is not passed, it is determined in the step S909 whether the program loop or the erase loop in step S907 is the maximum loop. If it is determined that it is the maximum loop, this program operation or the erase operation tails and the method also proceeds to S910. If it is not the maximum loop, the method goes hack to the step S907, an increased program voltage is applied in a next program loop, or an increased erase voltage is applied in the next erase loop.

In another exemplary embodiment, the predetermined condition for the controller 200 to write data into the second portion 120 is that a program operation or an erase operation in the first portion fails,

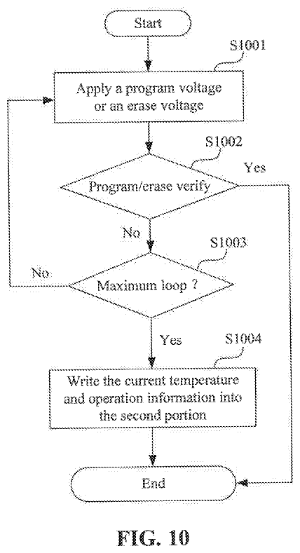

FIG. 10 is a flowchart of yet another exemplary operation method of the flash memory according to an embodiment of the present disclosure. When the processor 210 receives a program instruction or an erase instruction in the first portion, the operation method starts. As shown in FIG. 10, in step S1001, a program voltage is applied to the word line of the selected page, or an erase voltage is applied to the p-well. Next, in step S1002, a program verify or an erase verify is performed. If the program verify or the erase verify is passed, the method ends. If the program verify or the erase verify is not passed, the method proceeds to step S1003 in which it is determined whether the present operation loop is the maximum loop or not.

If the present operation loop is not the maximum loop, the method goes back to step S1001, and an increased program voltage or an increased erase voltage is applied.

If the present operation loop is the maximum loop, it is determined that the present operation fails, and the method proceeds to step S1004. In step S1004, the current temperature information and operation information are wrote into the second portion.

It should be noted that the process of writing the current temperature information and operation information into the second portion is steps S830, S910 and S1004 is a program operation on the second portion, and the program method illustrated in FIG. 7 may be used.

In various embodiments, the nonvolatile memory is at least one of a multimedia card (MMC) card, a Secure Digital (SD) card, a micro SD card, a memory stick, an ID card, a PCMCIA card, a chip card, a USB card, a smart card, and a Compact Flash (CP) card.

The nonvolatile memory may be packaged by a Package on Package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

While exemplary embodiments are described above, it is not intended that these embodiments describe all possible forms encompassed by the claims. The words used in the specification are words of description rather than limitation, and it is understood that various changes may be made without departing from the spirit and scope of the disclosure and claims. As previously described, the features of various embodiments may be combined to form further embodiments of the invention that may not be explicitly described or illustrated. While various embodiments may have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to: cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

1. A nonvolatile memory, comprising:
a memory cell array having a first portion and a second portion, wherein the first portion is programmable, readable and erasable to an end user, and the second portion is not programmable and erasable via operation of the end user;
a temperature sensor sensing a temperature of the memory cell array; and
a controller,
wherein the controller:
performs an operation in the first portion in response to an instruction of the end user, and
in response to determining that the sensed temperature of the memory cell array is outside of a predetermined range, writes into the second portion information regarding the sensed temperature of the memory cell array when doing the operation and operation information related to the operation performed.

2. (canceled)

3. (canceled)

4. (canceled)

5. The nonvolatile memory according to claim 1, wherein the operation performed in the first portion in response to the instruction of the end user is a program operation, the operation information comprises at least one of: an operation type, a magnitude of a program voltage, a sequence number of the program operation, a first status indicating whether the program operation succeeds or fails, a second status indicating whether the temperature of the memory cell array is within a predetermined range, and an address of memory cells in the first portion where the program operation is performed.

6. The nonvolatile memory according to claim 5, wherein an Incremental Step Pulse Program method is used in the program operation, the magnitude of the program voltage is a magnitude of an initial pulse, and the operation information further comprises a quantity of pulses used in the program operation and a quantity of memory cells failed to be programmed.

7. The nonvolatile memory according to claim 1, wherein the operation performed in the first portion in response to the instruction of the end user is an erase operation, the operation information comprises at least one of: an operation type, a magnitude of an erase voltage, a sequence number of the erase operation, a first status indicating whether the erase operation succeeds or fails, a second status indicating whether the temperature of the memory cell array is within a predetermined range, and an address of memory cells in the first portion where the erase operation is performed.

8. The nonvolatile memory according to claim 7, wherein an Incremental Step Pulse Erase method is used in the erase operation, the magnitude of the erase voltage is a magnitude of an initial pulse, and the operation information further comprises a quantity of pulses used in the erase operation and a quantity of memory cells failed to be erased.

9. The nonvolatile memory according to claim 1, wherein the second portion is a one-time program region of the nonvolatile memory.

10. The nonvolatile memory according to claim 1, wherein once the second portion is programmed, the second portion is permanently prevented from being programmed again and erased.

11. The nonvolatile memory according to claim 1, wherein the memory cell array comprises a plurality of blocks each comprising a plurality of pages, the plurality of blocks are divided into a first group serving as the first portion and a second group serving as the second portion.

12. The nonvolatile memory according to claim 1, wherein the end user is a purchaser of the nonvolatile memory.

13. A program method for a nonvolatile memory device, the nonvolatile memory device comprising: a memory cell array having a first portion and a second portion and a temperature sensor sensing a temperature of the memory cell array, wherein the first portion is programmable, readable and erasable via operation of an end user, and the second portion is not programmable and erasable via operation of the end user, the method comprising:
performing a program operation in the first portion in response to a program instruction of the end user;
sensing a temperature of the memory cell array when doing the program operation;
comparing the sensed temperature of the memory cell array to a predetermined temperature range for the memory cell array;
if the sensed temperature of the memory cell array is outside of the redetermined range, writing information regarding the sensed temperature of the memory cell array when doing the program operation and operation information related to the program operation into the second portion,
wherein the operation information comprises at least one of: an operation type, a magnitude of a program voltage, a sequence number of the program operation, a first status indicating whether the program operation succeeds or fails, a second status indicating whether the temperature of the memory cell array is within a predetermined range, and an address of memory cells in the first portion where the program operation is performed.

14. (canceled)

15. (canceled)

16. (canceled)

17. An erase method for a nonvolatile memory device, the nonvolatile memory device comprising: a memory cell array having a first portion and a second portion and a temperature sensor sensing a temperature of the memory cell array, wherein the first portion is programmable, readable and erasable via operation of an end user, and the second portion is not programmable and erasable via operation of the end user, the method comprising:
performing an erase operation in the first portion in response to an erase instruction of the end user, and
sensing a temperature of the memory cell array when doing the erase operation;
comparing the sensed temperature of the memory cell array to a predetermined temperature range for the memory cell array;
if the sensed temperature of the memory cell array is outside of the predetermined range, writing information regarding the sensed temperature of the memory cell array when doing the erase operation and operation information related to the erase operation into the second portion,
wherein the operation information comprises at least one of: an operation type, a magnitude of an erase voltage, a sequence number of the erase operation, a first status indicating whether the erase operation succeeds or fails, a second status indicating whether the temperature of the memory cell array is within a predetermined range, and an address of memory cells in the first portion where the erase operation is performed.

18. (canceled)

19. (canceled)

20. (canceled)

21. The nonvolatile memory according to claim 1, wherein the predetermined range is −40° C. to 85° C.

22. The nonvolatile memory according to claim 1, wherein the predetermined range is −40° C. to 105° C.

23. The nonvolatile memory according to claim 1, wherein the predetermined range is −40° C. to 125° C.

24. The program method according to claim 13, wherein the predetermined range is −40° C. to 85° C.

25. The program method according to claim 13, wherein the predetermined range is −40° C. to 105° C.

26. The program method according to claim 13, wherein the predetermined range is −40° C. to 125° C.

27. The erase method according to claim 17, wherein the predetermined range is −40° C. to 85° C.

28. The erase method according to claim 17, wherein the predetermined range is −40° C. to 105° C.

29. The erase method according to claim 17, wherein the predetermined range is −40° C. to 125° C.
